(19) United States
(12) Patent Application Publication
(10) Pub. No.: US 2025/0046362 A1
(43) Pub. Date: Feb. 6, 2025

(54) HYBRID MEMORY CHIP AND MEMORY SYSTEM, COMPUTING APPARATUS INCLUDING THE SAME

(71) Applicant: Etron Technology, Inc., Hsinchu (TW)

(72) Inventor: Chun Shiah, Hsinchu (TW)

(73) Assignee: Etron Technology, Inc., Hsinchu (TW)

(21) Appl. No.: 18/793,955

(22) Filed: Aug. 5, 2024

Related U.S. Application Data
(60) Provisional application No. 63/530,703, filed on Aug. 4, 2023.

(51) Int. Cl. G11C 11/4096; G11C 11/4091; G11C 11/4097

(52) U.S. Cl. CPC G11C 11/4096; G11C 11/4091; G11C 11/4097

(57) ABSTRACT

A hybrid memory chip as well as a memory system and a computing apparatus including the hybrid memory chip are provided. The hybrid memory chip includes: dynamic random access memory (DRAM) arrays; sense amplifier arrays, disposed around each of the DRAM arrays; and static random access memory (SRAM) arrays, disposed around each of the DRAM arrays, and respectively abutted with one of the sense amplifier arrays. The sense amplifier arrays are configured to perform read operations from the DRAM arrays and the SRAM arrays. Bit lines across the DRAM arrays extend through the sense amplifier arrays and the SRAM arrays.

### CROSS-REFERENCE TO RELATED APPLICATION

This application claims the priority benefit of U.S. provisional application Ser. No. 63/530,703, filed on Aug. 4, 2023. The entirety of the above-mentioned patent application is hereby incorporated by reference herein and made a part of this specification.

### BACKGROUND

### Technical Field

Embodiments of the present disclosure are related to a memory chip as well as a memory system and a computing apparatus including the memory chip, and more particularly, to a hybrid memory chip as well as a memory system and a computing apparatus including the hybrid memory chip.

### Description of Related Art

In practice, a memory system is a hierarchy of storage devices with different capacities, costs, and access times. As shown in FIG. 1, small, fast cache memory C102 (such as SRAM) integrated with a central processing unit (CPU) C100 in a processor chip C104 acts as a staging area for a subset of the data and instructions stored in the relatively slow main memory C106. The main memory C106 in turn stages data stored on large, slow disks.

On the other hand, system bus C110 is used to transfer data between the storage devices at different levels, such as the cache memory C102 and the main memory C106. While more data can be handled by the CPU C100 and the storage devices, data transfer along the system bus C110 is no longer fast enough, and has become a bottleneck of the entire computing system. No matter how fast a given CPU can work, it is limited by a rate of transfer allowed by the system bus.

As being a frequently accessed storage device, the main memory C106 (such as DRAM) includes memory arrays/core circuit C112 and peripheral circuits (such as address decoder, command decoder, word line drivers C114 and more). Memory cells in each memory array C112 are respectively addressed at an intersection of a bit line BL and a word line WL. While the word lines WL extend to the word line drivers C114 along a first direction, the bit lines BL may extend to the sense amplifier arrays C112 along a second direction, and data stored in the memory cells can be read out through the sense amplifiers in the sense amplifier arrays C112.

On the other hand, storage memory plays a key role in the high performance computing (HPC) and artificial intelligence (AI) application. How to provide efficient and speedy storage memory for HPC and AI is crucial and important.

### SUMMARY

In an aspect of the present disclosure, a hybrid memory chip is provided. The hybrid memory chip comprises: dynamic random access memory (DRAM) arrays; sense amplifier arrays, adjacent to the DRAM arrays; and static random access memory (SRAM) arrays, adjacent to the DRAM arrays or the sense amplifier arrays, and one of static random access memory (SRAM) arrays respectively abutted with one of the sense amplifier arrays, wherein the sense amplifier arrays are configured to perform access operations between the DRAM arrays and the SRAM arrays.

In some embodiments, bit lines across the DRAM arrays extend through the sense amplifier arrays and the SRAM arrays. In addition, the SRAM arrays are configured to be written with data stored in the DRAM arrays through the bit lines, or the DRAM arrays are configured to be written with data stored in the SRAM arrays through the bit lines.

In some embodiments, the hybrid memory chip further comprises: word line drivers, adjacent to the DRAM arrays, the sense amplifier arrays and the SRAM arrays, wherein word lines across the DRAM arrays and the SRAM arrays extend to the word line drivers.

In some embodiments, the DRAM arrays, the SRAM arrays, the sense amplifier arrays and the word line drivers are configured to perform a copy operation copying data stored in a single cell of one of the DRAM arrays to a single cell of one of the SRAM arrays, or copying data stored in another single cell of one of the SRAM arrays to another single cell of one of the DRAM arrays.

In some embodiments, the DRAM arrays, the SRAM arrays, the sense amplifier arrays and the word line drivers are configured to perform a copy operation copying data pattern stored in multiple cells of one of the DRAM arrays to multiple cells of one of the SRAM arrays, or copying data pattern stored in multiple cells of one of the SRAM arrays to multiple cells of one of the DRAM arrays.

In some embodiments, data pattern stored in a row of cells of one of the DRAM arrays are copied to a row of cells in one of the SRAM arrays during the copy operation, or data pattern stored in a row of cells of one of the SRAM arrays are copied to a row of cells in one of the DRAM arrays during the copy operation.

In some embodiments, two adjacent ones of the DRAM arrays are spaced apart from each other with one of the sense amplifier arrays and one of the SRAM arrays in between.

In some embodiments, two adjacent ones of the DRAM arrays are spaced apart from each other with one of the sense amplifier arrays and two of the SRAM arrays in between.

In some embodiments, each of the sense amplifier arrays is interposed between two of the SRAM arrays.

In another aspect of the present disclosure, a memory system is provided. The memory system comprises: a first primary memory integrated with a central processing unit (CPU) in a processor chip and comprising first static random access memory (SRAM) arrays; a second primary memory, external to the processor chip and comprising second SRAM arrays; and a main memory, comprising dynamic random access memory (DRAM) arrays and integrated with the second primary memory in a hybrid memory chip.

In some embodiments, the second primary memory is configured to store data provided from the main memory, and data transfer between the second primary memory and the main memory is implemented without using an external bus extending between the processor chip and the hybrid memory chip.

In some embodiments, the second SRAM arrays of the second primary memory are abutted with sense amplifier arrays around the DRAM arrays of the main memory in the hybrid memory chip.

In some embodiments, bit lines across the DRAM arrays of the main memory extend through the sense amplifier arrays and the second SRAM arrays of the second primary memory. In yet another aspect of the present disclosure, a computing apparatus is provided. The computing apparatus comprises: a processor chip, in which a central processing unit (CPU) and a first primary memory are integrated, wherein the first primary memory comprises first static random access memory (SRAM) arrays; and a hybrid memory chip, in connection with the processor chip via an external bus, wherein a second primary memory and a main memory are integrated in the hybrid memory chip, the second primary memory comprises second SRAM arrays, and the main memory is formed of dynamic random access memory (DRAM) arrays.

In some embodiments, the second primary memory is configured to store data provided from the main memory, and data transfer between the second primary memory and the main memory is implemented without using the external bus.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 is a schematic diagram illustrating a portion of a conventional memory system.

FIG. 2 is a schematic diagram illustrating memory arrays surrounded by word line decoders and sense amplifiers in a conventional memory system.

FIG. 3A is a schematic diagram illustrating a portion of a memory system according to some embodiments of the present disclosure, and FIG. 3B schematically depicts configuration and data transfer between DRAM arrays and SRAM arrays in the hybrid memory chip of the memory system.

FIG. 4A is a schematic diagram illustrating a hybrid memory chip, according to some embodiments of the present disclosure, and FIG. 4B schematically depicts configuration and data transfer between DRAM arrays and SRAM arrays in the hybrid memory chip of the memory system.

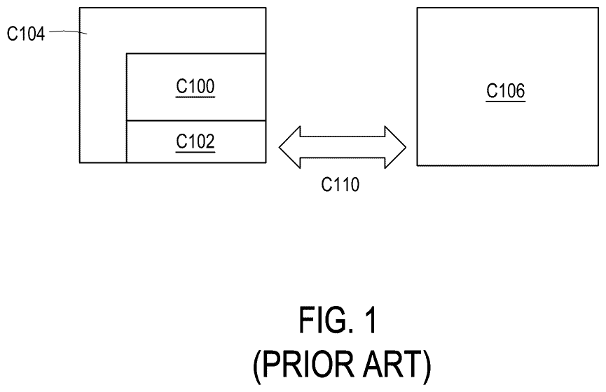

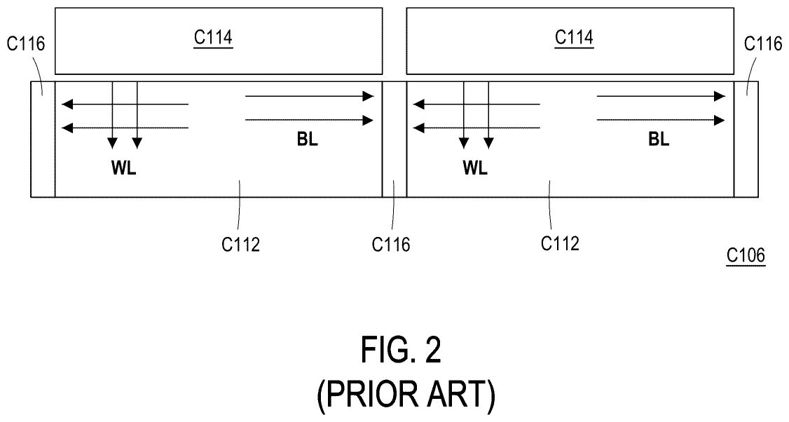

### DESCRIPTION OF THE EMBODIMENTS

Embodiments of the present disclosure provide a solution for overcoming the memory bottleneck resulted from slow data transfer along the system bus.

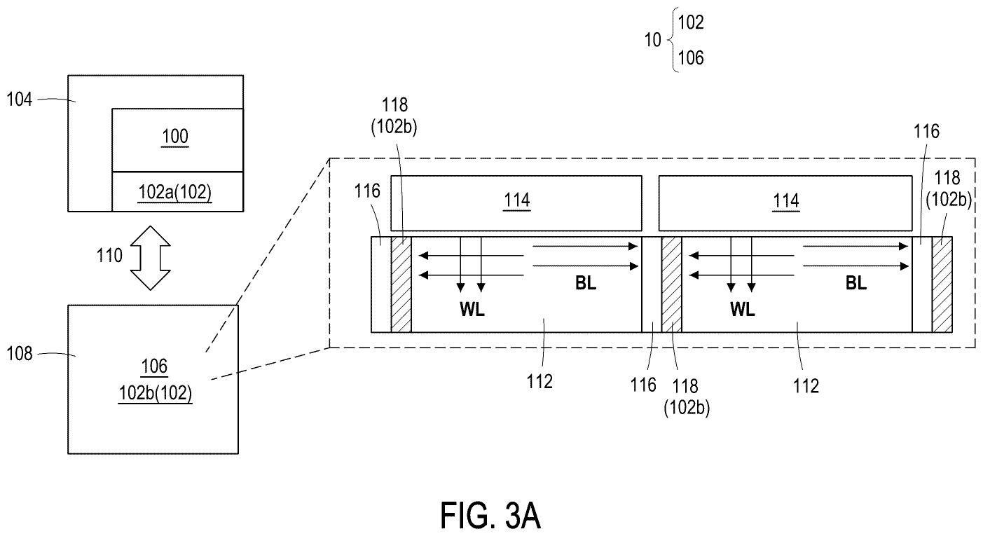

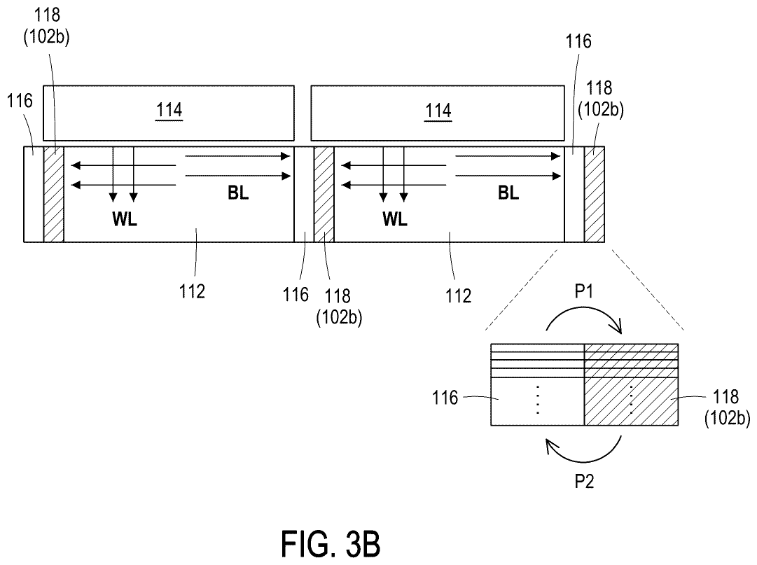

FIG. 3A is a schematic diagram illustrating a portion of a memory system 10 according to some embodiments of the present disclosure.

The memory system 10 (partially depicted FIG. 3A) is hierarchical, based on speed, cost and capacity of the memory devices therein. Such hierarchy is essentially employed to organize the memory devices in such a way that data access time can be minimized, thus improving performance of the computing apparatus. At top of the memory hierarchy, a primary memory 102 (such as SRAM) with the highest speed can store small amount of most frequently used data and instructions. A first part of the primary memory 102 (also referred to as a primary memory 102a) may be integrated with the CPU 100 in a processor chip 104, which may be provided by an application specific integrated chip (ASIC). In this way, communication between the primary memory 102a and the CPU 100 can be efficiently implemented by internal routings of the processor chip 104. Further, as will be described in greater details, a second part of the primary memory 102 (also referred to as a primary memory 102b) is integrated with a main memory 106 (such as DRAM) in a hybrid memory chip 108, to avoid from inter-chip communication therebetween.

The data and instructions temporarily stored by the primary memory 102 are provided from the main memory 106, which is greater in storage capacity and usually slower in speed as compared to the primary memory 102. While the primary memory 102 and the main memory 106 are both volatile memories, the primary memory 102 is provided by static random access memory (SRAM), and the main memory 106 is provided by dynamic random access memory (DRAM). That is, the hybrid memory chip 108 containing both the main memory 106 and the primary memory 102b is integrated with DRAM and SRAM.

As being arranged with the main memory 106 in the same chip, the primary memory 102b can be communicated with the slower main memory 106 via in-chip data paths, which are considerably shorter than the inter-chip data paths. Accordingly, data transfer between the primary memory 102 and the slower main memory 106 can be realized with minimum latency. On the other hand, the primary memory 102b in the hybrid memory chip 108 may be communicated with the primary memory 102a in the processor chip 104 via inter-chip data paths provided by an external bus 110. Nevertheless, since frequent communication to the slow main memory 106 is no longer implemented through the external bus 110, speed of the inter-chip communication through the external bus 110 may be effectively improved.

To reduce area penalty, the primary memory 102b is integrated with the main memory 106 in a particular way. Specifically, the DRAM providing the main memory 106 includes DRAM arrays 112, and includes peripheral circuits disposed around the DRAM arrays 112 and configured to control read and write of cells in the DRAM arrays 112. In addition to word line drivers 114 respectively arranged aside one of the DRAM arrays 112, sense amplifier arrays 116 are arranged to each DRAM array 112. Word lines WL across the DRAM arrays 112 may extend along a row direction to reach the word line drivers 114, whereas bit lines BL across the DRAM arrays 112 may extend along a column direction to the sense amplifier arrays 116. Given that cells consisting SRAM arrays 118 of the primary memory 102b and cells consisting the sense amplifier arrays 116 in the DRAM of the main memory 106 both include latch circuits as main architecture, they can be highly similar with each other in terms of circuit and layout design. Based on such similarity, the primary memory 102b are laid adjacent to the sense amplifier arrays 116, to reduce area penalty.

To be more specific, since the SRAM arrays 118 and the sense amplifier arrays 116 are highly similar with each other in terms of circuit and layout, they may be laid in cells with similar or even identical dimensions, and may have similar pattern density. In this way, large isolation area is not required to separate the SRAM arrays 118 and the sense amplifier arrays 116. In certain cases, the SRAM arrays 118 may even abut the sense amplifier arrays 116 without an isolation area in between.

In some embodiments, each sense amplifier array 116 may be disposed along a certain side of one of the DRAM arrays 112, and the bit lines BL across the DRAM arrays 112 extend through the sense amplifier arrays 116, such that data stored in the DRAM arrays 112 can be read out by the sense amplifier arrays 116 through the bit lines BL. In addition, the SRAM arrays 118 may be respectively in lateral contact with a corresponding one of the DRAM arrays 112 and one of the sense amplifier arrays 116, and the bit lines BL may extend through the SRAM arrays 118 as well. Based on such configuration, data stored in the SRAM arrays 118 can also be read out by the sense amplifier arrays 116 through the bit lines BL. That is, the sense amplifier arrays 116 can be shared by the DRAM arrays 112 and the SRAM arrays 118.

Furthermore, as the bit lines BL extend across both the DRAM arrays 112 and the SRAM arrays 118, write to the DRAM arrays 112 and the SRAM arrays 118 can be both implemented through the bit lines BL. In this way, the data stored in the DRAM arrays 112 can be sensed from the bit lines BL by the sense amplifier arrays 116, and can be written to the SRAM arrays 118 through the bit lines BL as well. Or the other way around, the data stored in the SRAM arrays 118 can be read out from the bit lines BL by the sense amplifier arrays 116, and can be written to the DRAM arrays 112 through the bit lines BL as well. Such data transfer from the DRAM arrays 112 to the SRAM arrays 118 (and vice versa) is carried out in the hybrid memory chip 108, and inter-chip data transmission through the external bus 110 is avoided. Therefore, as described, frequent communication to the relatively slower main memory 106 is no longer implemented through the inter-chip paths provided by the external bus 110, and speed of the inter-chip communication through the external bus 110 may be effectively improved.

Although not shown, additional word lines may extend across the SRAM arrays 118, and enable row selection during read and write of the SRAM arrays 118. In some embodiments, the word line drivers 114 are expanded to be shared by both the DRAM arrays 112 and the SRAM arrays 118. In these embodiments, the word line drivers 114 may further extend along the SRAM arrays 118, and the additional word lines across the SRAM arrays 118 may extend along a row direction to the word line drivers 114.

According to some embodiments, each SRAM array 118 is as about the same capacity as the adjacent sense amplifier array 116. The term “capacity” used herein indicates cell counts, and may further indicate array dimensions. As an example, each DRAM array 112 has 512 columns of cells, and is connected to 16 input/output pins. Accordingly, each DRAM arrays 112 may require 8 k bit line sense amplifiers. The sense amplifier arrays 116 at opposite sides of each DRAM array 112 may respectively include 4 k of the bit line sense amplifiers. Likewise, the SRAM arrays 118 at opposite sides of each DRAM array 112 may respectively include 4 k of

SRAM cells. As further indicated by FIG. 3B, based on similarities in between, the SRAM arrays 118 can be described as extension of the sense amplifier arrays 116. In the example that 4K of the bit line sense amplifiers 116 are arranged along one side of the adjacent DRAM array 112, another 4K of the SRAM cells are placed next to the 4K of the bit line sense amplifiers, as extension of these bit line sense amplifiers.

During a copy operation to transfer a single-bit data from one of the DRAM arrays 112 to one of the SRAM arrays 118, the data stored in a selected cell in the DRAM 112 is read out in response to selection of a column address and a row address of the DRAM array 112. That is, the cell at intersection of the selected word line WL and selected bit line BL is read out by the bit line sense amplifier connected to the selected bit line BL. Thereafter, in response to selection of a row address of the SRAM array 118, this data is written to a cell at an intersection of the selected word line WL of the SRAM array 118 and the selected bit line BL shared by the DRAM array 112 and the SRAM array 118. As a result, the data stored in the selected cell of the DRAM array 112 is copied to the selected cell in the SRAM array 118. In a similar way, a copy operation can be performed to transfer a single-bit data from one of the SRAM arrays 118 to one of the DRAM arrays 112.

Besides single-bit transfer, multi-bit transfer can be realized in a single copy operation from one of the DRAM arrays 112 to one of the SRAM arrays 118 (and vice versa). For example, data pattern stored in a row of cells in the DRAM array 112 can be read out in response to selection of multiple column addresses and a row address of the DRAM array 112. That is, the row of cells at intersections of the selected word line WL and the selected bit lines BL are sensed by the bit line sense amplifiers connected to the selected bit lines BL. Thereafter, in response to selection of a row address of the SRAM array 118, this data pattern is written to a row of cells at intersections of the selected word line WL of the SRAM array 118 and the selected bit lines BL shared by the DRAM array 112 and the SRAM array 118. As a result, the data pattern stored in the selected row of cells in the DRAM array 112 is copied to the selected row of cells in the SRAM array 118. In a similar way, a copy operation can be performed to transfer a data pattern from one of the SRAM arrays 118 to one of the DRAM arrays 112. In certain cases, a data pattern stored in multiple rows of cells in one of the DRAM arrays 112 can be copied to selected rows of cells in the corresponding SRAM array 118.

As schematically shown by FIG. 3B, for either the single-bit transfer or the multi-bits transfer, data transfer between each of the DRAM arrays 112 and an adjacent SRAM array 118 can go through the sense amplifier array 116 shared by them, along in-chip paths P1. On the other hand, data transfer between each of the SRAM arrays 118 and an adjacent DRAM array 112 can go through the sense amplifier array 116 shared by them, along in-chip paths P2. For example, 8K bits (4K each side) can be copied simultaneously from DRAM arrays 112 and two sense amplifier arrays 116 to corresponding adjacent SRAM arrays 118, or 8K bits (4K each side) can be copied simultaneously from SRAM array 118 to corresponding sense amplifier arrays 116 and DRAM arrays 112. COPY speed is 512× improved when column address is 512.

Specifically, to execute the copy command, selection of a word line WL is performed according to a selected row address (such as Row address “RAn” and Row Section Address “RAsec”), while selection of one or more bit line(s) BL is performed according to one or more column address(es) “CAn”. When an instruction to copy data from a SRAM array 118 to a DRAM array 112 (“S2D Copy Command”) is given, data stored in the selected SRAM cell(s) of the SRAM array 118 is simultaneously written to corresponding bit line sense amplifier(s) according to the given row address(es) and the given row section address. For example, S2D COPY command with RAn, RAsec can be issued to write simultaneously from 8K bits of the two SRAM array 118 into their corresponding sense amplifier arrays 116 and DRAM array 112 based in the given address Ran and RAsec.

On the other hand, when an instruction to copy data from a DRAM array 112 to a SRAM array 118 is given (“D2S Copy Command”), data read to bit line sense amplifier(s) from the DRAM array 112 is simultaneously written to corresponding SRAM cell(s) of the SRAM array 118, based on the given row address(es) and the given row section address. For example, D2S COPY command with RAn, RAsec can be issued to write simultaneously from DRAM array 112 and 8K bits of the sense amplifier arrays 116 into their corresponding two SRAM array 118 based in the given address Ran and RAsec.

Any SRAM cell in the hybrid memory chip 108 can be accessed with a column address, a row section address and a row address, under specified SRAM timing criteria. In addition, any DRAM cell in the hybrid memory chip 108 can be accessed with a column address, a row section address and a row address, under specified DRAM timing criteria. Further, the DRAM arrays 112 and the SRAM arrays 118 in the hybrid memory chip 108 can share the input/output pins, or have different sets of input/output pins.

As compared to data transfer through the external bus 110, the data transfer by the copy operation within the hybrid memory chip 108 is much faster and consumes much less power, since one copy operation can replace many repeats of reading and writing through the external bus 110. In some embodiments, as compared to transferring data between main memory and primary memory by using external bus, the data transfer between the main memory 106 and the primary memory 102b within the hybrid memory chip 108 is about 400 times faster, and power consumption is reduced by about 100 times.

In the embodiments described with reference to FIG. 3A and FIG. 3B, the sense amplifier arrays 116 and the SRAM arrays 118 in the hybrid memory chip 108 may have about the same capacity. In alternative embodiments, the SRAM arrays 118 are greater in capacity than the sense amplifier arrays 116 in the hybrid memory chip 108.

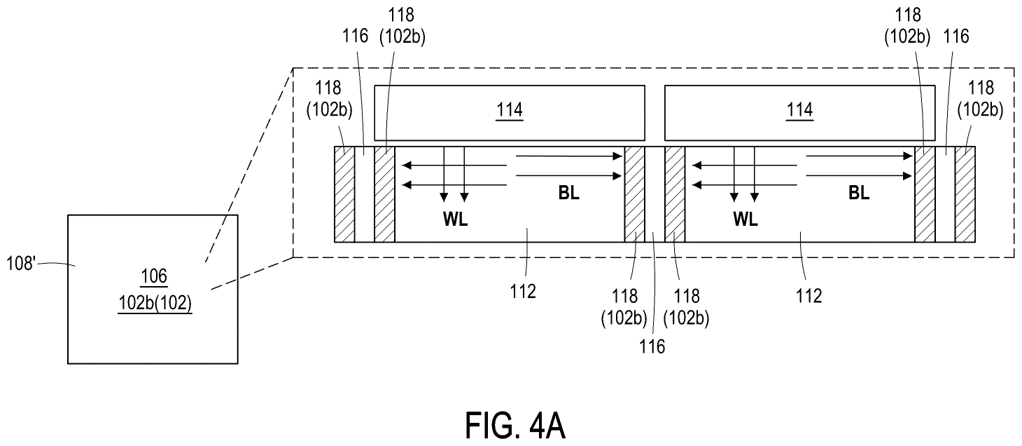

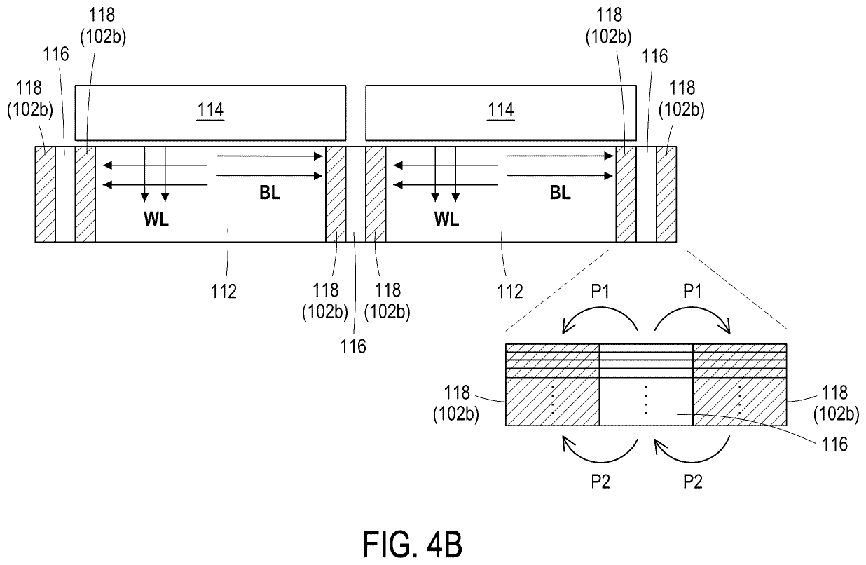

FIG. 4A is a schematic diagram illustrating a hybrid memory chip 108′, according to some embodiments of the present disclosure. The hybrid memory chip 108′ is similar to the hybrid memory chip 108 described with reference to FIG. 3A and FIG. 3B, except that the hybrid memory chip 108′ has more of the SRAM arrays 118. For instance, in the hybrid memory chip 108′, capacity of the SRAM arrays 118 may be about twice as capacity of the sense amplifier arrays 116. Specifically, along a single side of each DRAM array 112 in the hybrid memory chip 108′, one of the sense amplifier arrays 116 may be disposed between a pair of the SRAM arrays 118, and each of the sense amplifier arrays 116 may be in contact with the adjacent DRAM arrays 112 via the SRAM arrays 118 at opposite sides. As each sense amplifier array 116 and each SRAM array 118 are substantially identical with each other in terms of capacity, a total capacity of the SRAM arrays 118 may be about twice as a total capacity of the sense amplifier arrays 116.

In the example that each DRAM array 112 has 512 columns of cells and is connected to 16 input/output pins, the sense amplifier array 116 may respectively include 4 k of the sense amplifiers. Likewise, the SRAM arrays 118 may respectively include 4 k of SRAM cells. That is, at a single side of each DRAM array 112, there may be 4 k of the sense amplifiers and 8 k of the SRAM cells.

As further indicated by FIG. 4B based on similarities in between, the SRAM arrays 118 can be described as extension of the sense amplifier arrays 116. In the example that 4K of the bit line sense amplifiers 116 are arranged along one side of the adjacent DRAM array 112, 8K of the SRAM cells are placed at opposite sides of the 4K of the bit line sense amplifiers, as extension of these bit line sense amplifiers.

Owing to high similarity in circuit and layout between the sense amplifier arrays 116 and the SRAM arrays 188, a large isolation area between each SRAM array 118 and the adjacent sense amplifier array 116 may not be required. In certain cases, the SRAM arrays 118 abut the sense amplifier arrays 116 without an isolation area in between.

As the bit lines BL across the DRAM arrays 112 extend through the SRAM arrays 118 and the sense amplifiers 116, the sense amplifier arrays 116 can also be shared by the DRAM arrays 112 and the SRAM arrays 118 for read operations. In addition, data stored in the DRAM arrays 112 can be read out from the bit lines BL by the sense amplifiers, and then written to the SRAM arrays 118, without traveling through the inter-chip paths provided by the external bus 110. Likewise, data stored in the SRAM arrays 118 can be read out from the bit lines BL by the sense amplifiers, and then written to the SRAM arrays 118, without traveling through the inter-chip paths provided by the external bus 110.

In some embodiments, single-bit data transfer can be implemented in a copy operation from one of the DRAM arrays 112 to one of the SRAM arrays 118, and vice versa. In other embodiments, multi-bit data transfer can be implemented in a copy operation from one of the DRAM arrays 112 to one of the SRAM arrays 118, and vice versa. As schematically shown by FIG. 4B, for either the single-bit transfer or the multi-bit transfer, data from each of the DRAM arrays 112 can go through the in-chip paths P1 to an adjacent SRAM array 118. On the other hand, data from each of the SRAM arrays 118 can go through the in-chip paths P2 to an adjacent DRAM array 112.

As there are additional word lines (not shown) extending across the SRAM arrays 118 to enable row selection during operation of the SRAM arrays 118, the word line drivers 114 may be expanded to be shared by both the DRAM arrays 112 and the SRAM arrays 118. In some embodiments, the word line drivers 114 may further extend along the SRAM arrays 118, and the additional word lines across the SRAM arrays 118 may extend along a row direction to the word line drivers 114.

Although not particularly depicted, the hybrid memory chip 108′ may also be used in a memory system, of which another part of its primary memory is external to the hybrid memory chip 108′ and communicated with the hybrid memory chip 108′ via an external bus. It should be noted that, such memory system can also be applied in a computing apparatus described with reference to FIG. 3A.

In the event it is necessary to write data from the processor chip C104 to the DRAM arrays 112 of the hybrid memory, the data could be written into the SRAM array 118 of the hybrid memory without waiting for any refresh/latency of DRAM arrays 112, and then the written data could be transferred from the SRAM array 118 of the hybrid memory to the DRAM arrays 112.

Thus, the processor chip C104 does not have to wait for the refresh/latency period of DRAM arrays 112.

In some embodiments, either in the memory system 10 described with reference to FIG. 3A and FIG. 3B or the memory system described with reference to FIG. 4A and FIG. 4B, the primary memory 102 may have different levels of SRAMs, such as 3 or more levels of SRAMs.

As compared to a SRAM at a higher level, a SRAM at a lower level may have a larger footprint area. To release more chip area from the processor chip 104, the SRAM(s) at lower level(s) may be integrated with the main memory 106 in the hybrid memory chip 108/108′. As an example, while SRAMs of first and second levels are integrated in the processor chip 104 as the primary memory 102a, SRAM of third level is integrated in the hybrid memory chip 108/108′ as the primary memory 102b.

Further, although not shown, the memory system 10 containing the hybrid memory chip 108 as described with reference to FIG. 3A, FIG. 3B and the memory system 10 containing the hybrid memory chip 108′ as described with reference to FIG. 4A, FIG. 4B may respectively include memories of lower level(s), such as non-volatile memory and/or hard disk.

As above, a solution is provided for overcoming the memory bottleneck resulted from slow data transfer along the system bus. Conventionally, a primary memory (such as SRAM) is embedded in a processor chip, while a slower main memory (such as DRAM) is formed in another chip. As a consequence, data transfer between the primary memory and the slower main memory has to run through inter-chip data paths provided by an external bus, thus considerable write/read latency is resulted. According to embodiments of the present disclosure, a portion of a primary memory is integrated with a main memory in a hybrid memory chip (that is, the DRAM and SRAM could be integrated into a single semiconductor chip), and latency and power consumption of data transfer between the primary memory and the main memory can be significantly reduced. Thus, access operations (read or write operation) between the DRAM and SRAM could be efficient.

Further, as SRAM cells and sense amplifiers used for reading/writing DRAM cells are highly similar in terms of layout, circuit and pattern density, the primary memory (such as SRAM) can be integrated with the main memory (such as DRAM) by least area penalty. Moreover, peripheral circuits around the DRAM cells can be shared with the SRAM cells.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A hybrid memory chip, comprising:
dynamic random access memory (DRAM) arrays;
sense amplifier arrays, adjacent to the DRAM arrays; and
static random access memory (SRAM) arrays, adjacent to the DRAM arrays or the sense amplifier arrays, and one of static random access memory (SRAM) arrays respectively abutted with one of the sense amplifier arrays,
wherein the sense amplifier arrays are configured to perform access operations between the DRAM arrays and the SRAM arrays.

2. The hybrid memory chip according to claim 1,
wherein bit lines across the DRAM arrays extend through the sense amplifier arrays and the SRAM arrays,
wherein the SRAM arrays are configured to be written with data stored in the DRAM arrays through the bit lines, or the DRAM arrays are configured to be written with data stored in the SRAM arrays through the bit lines.

3. The hybrid memory chip according to claim 1, further comprising:
word line drivers, adjacent to the DRAM arrays, the sense amplifier arrays and the SRAM arrays, wherein word lines across the DRAM arrays and the SRAM arrays extend to the word line drivers.

4. The hybrid memory chip according to claim 3, wherein the DRAM arrays, the SRAM arrays, the sense amplifier arrays and the word line drivers are configured to perform a copy operation copying data stored in a single cell of one of the DRAM arrays to a single cell of one of the SRAM arrays, or copying data stored in another single cell of one of the SRAM arrays to another single cell of one of the DRAM arrays.

5. The hybrid memory chip according to claim 3, wherein the DRAM arrays, the SRAM arrays, the sense amplifier arrays and the word line drivers are configured to perform a copy operation copying data pattern stored in multiple cells of one of the DRAM arrays to multiple cells of one of the SRAM arrays, or copying data pattern stored in multiple cells of one of the SRAM arrays to multiple cells of one of the DRAM arrays.

6. The hybrid memory chip according to claim 5, wherein data pattern stored in a row of cells of one of the DRAM arrays are copied to a row of cells in one of the SRAM arrays during the copy operation, or data pattern stored in a row of cells of one of the SRAM arrays are copied to a row of cells in one of the DRAM arrays during the copy operation.

7. The hybrid memory chip according to claim 1, wherein two adjacent ones of the DRAM arrays are spaced apart from each other with one of the sense amplifier arrays and one of the SRAM arrays in between.

8. The hybrid memory chip according to claim 1, wherein two adjacent ones of the DRAM arrays are spaced apart from each other with one of the sense amplifier arrays and two of the SRAM arrays in between.

9. The hybrid memory chip according to claim 8, wherein each of the sense amplifier arrays is interposed between two of the SRAM arrays.

10. A memory system, comprising:
a first primary memory integrated with a central processing unit (CPU) in a processor chip and comprising first static random access memory (SRAM) arrays;
a second primary memory, external to the processor chip and comprising second SRAM arrays; and
a main memory, comprising dynamic random access memory (DRAM) arrays and integrated with the second primary memory in a hybrid memory chip.

11. The memory system according to claim 10, wherein the second primary memory is configured to store data provided from the main memory, and data transfer between the second primary memory and the main memory is implemented without using an external bus extending between the processor chip and the hybrid memory chip.

12. The memory system according to claim 10, wherein the second SRAM arrays of the second primary memory are abutted with sense amplifier arrays around the DRAM arrays of the main memory in the hybrid memory chip.

13. The memory system according to claim 12, wherein bit lines across the DRAM arrays of the main memory extend through the sense amplifier arrays and the second SRAM arrays of the second primary memory.

14. A computing apparatus, comprising:
a processor chip, in which a central processing unit (CPU) and a first primary memory are integrated, wherein the first primary memory comprises first static random access memory (SRAM) arrays; and
a hybrid memory chip, in connection with the processor chip via an external bus, wherein a second primary memory and a main memory are integrated in the hybrid memory chip, the second primary memory comprises second SRAM arrays, and the main memory is formed of dynamic random access memory (DRAM) arrays.

15. The computing apparatus according to claim 14, wherein the second primary memory is configured to store data provided from the main memory, and data transfer between the second primary memory and the main memory is implemented without using the external bus.
